(19) United States
(12) Patent Application Publication
(10) Pub. No.: US 2026/0198448 A1
(43) Pub. Date: Jul. 16, 2026

(54) MILKING PLANT, COMPUTER-IMPLEMENTED METHOD, COMPUTER PROGRAM AND NON-VOLATILE DATA CARRIER

(71) Applicant: DELAVAL HOLDING AB, Tumba (SE)

(72) Inventor: Anders UMEGÅRD, Tumba (SE)

(21) Appl. No.: 19/132,622

(22) PCT Filed: Nov. 21, 2023
(86) PCT No.: PCT/SE2023/051171

§ 371 Date: May 23, 2025

(30) Foreign Application Priority Data
Nov. 25, 2022 (SE) 2251374-1

(51) Int. Cl. A01J 5/01; H03M 7/30

(52) U.S. Cl. CPC A01J 5/01; H03M 7/3059

(57) ABSTRACT

A milking plant has at least one milking point arranged to extract milk from an animal, which milking point contains at least one sensor device configured to produce milking-related raw data during extraction of milk from the animal. At least one processing unit obtains a primary data set containing an original number of data values representing the milking-related raw data, and obtains a data compressing parameter forming a basis for a secondary data set including a reduced number of data positions, which reduced number is lower than the original number. The at least one processing unit maps the original number of data values onto the reduced number of data positions to generate the secondary data set by applying at least one data compression algorithm, and outputs the secondary data set via an output interface to enable storage of the secondary data set in at least one data store.

### CROSS-REFERENCE TO RELATED APPLICATIONS

This application is the U.S. national phase of International Application No. PCT/SE2023/051171 filed Nov. 21, 2023, which designated the U.S. and claims priority to SE Patent Application No. 2251374-1 filed Nov. 25, 2022, the entire contents of each of which are hereby incorporated by reference.

### TECHNICAL FIELD

The present invention generally concerns technology for obtaining and processing parameters relating to milk extraction. Especially, the invention relates to a milking plant according to the preamble of claim 1. The invention also relates to a computer-implemented method relating to the proposed milking plant, a computer program and a non-volatile data carrier storing such a computer program.

### BACKGROUND

For efficient and animal-friendly handling of dairy animals it is important to keep track of each animal's key characteristics in terms of physiological and behavioral parameters. In particular, of course, any factors that describe or by other means reflect the milk extraction process are specially vital to log and follow up. Thus, not only parameters that relate to the animals as such are significant, however also data demonstrating each animal's interaction with the milking equipment and/or how the milking equipment was operated when milk was extracted from individual animals may be relevant to consider.

EP 3 187 041 and EP 3 199 020 describe an adaptive milking system comprising a memory operable to store a default threshold flow rate; and a processor operable to: measure a flow rate of milking an animal during a first period of time, calculate a percentage of the measured flow rate; monitor the flow rate of milking the animal; trigger a delay timer when the monitored flow rate of milking the animal becomes lower than the larger of: (a) a default threshold flow rate and (b) the calculated percentage of the measured flow rate; and generate a control signal to stop the milking process when the delay timer reaches a threshold time.

For example, a milk meter may measure and record measurement data in the form of an average flow rate, a current flow rate, teat flow rates, milking duration, milk yield, milking unit attachment time, milk flow rate at stop, as well as other suitable information used to manage an adaptive milking process according to system.

However, for technical and practical reasons, there are constrains to the amount of data that can be registered and stored. Different parameters are differently important, and deviate dramatically from one another in terms of when and how much they fluctuate. It is therefore complicated to filter out redundant data and only store the most relevant data.

### SUMMARY

Consequently, the object of the present invention is to offer a solution that is capable of collecting and storing milking-related data in an efficient and reliable manner that enables advanced analyses of the milking process and the animals involved in this process.

According to one aspect of the invention, the object is achieved by a milking plant including at least one milking point and at least one processing unit. The at least one milking point is arranged to extract milk from an animal, and the at least one milking point, in turn, includes at least one sensor device configured to produce milking-related raw data during extraction of milk from the animal, which data for example covers a complete milking session during which milk was extracted from the animal. The at least one processing unit is configured to obtain a primary data set containing an original number of data values representing the milking-related raw data. The at least one processing unit is also configured to obtain a data compressing parameter forming a basis for a secondary data set containing a reduced number of data positions, which reduced number is lower than the original number. The at least one processing unit is further configured to map the original number of data values onto the reduced number of data positions to generate the secondary data set by applying at least one data compression algorithm, and output the secondary data set via an output interface to enable storage of the secondary data set in at least one data store.

This milking plant is advantageous because it provides a highly flexible handling of milking-related data both for immediate analysis and for subsequent evaluation.

According to one embodiment of this aspect of the invention, the secondary data set represents a non-uniform sampling of the primary data set. The non-uniform sampling is such that intermediate distances between the sampling points in a set of sampling points represented by the reduced number of data positions in the secondary data set is inversely correlated with an information density of a signal underlying the milk-related raw data. Thus, the sampling intervals in the secondary data set may be adaptively adjusted to match any local variations in the information density of the signal underlying the milk-related raw data.

According to a further embodiment of this aspect of the invention, the milking-related raw data further contains respective information identifying each of the at least one milking point in which the at least one sensor device is comprised. Thereby, it is straightforward to analyze various aspects of the milking process in terms of the technical characteristics of the respective milking points used.

According to another embodiment of this aspect of the invention, the at least one processing unit is configured to apply the at least one data compression algorithm by adapting the mapping of the original number of data values onto the reduced number of data positions to a slope variability in the primary data set, such that a first subset of the primary data set, which first subset represents a sequence of an amount of consecutive data values and has a first slope variance value is mapped onto a larger number of the available number of data positions in the secondary data set than a second subset of the primary data set if the second subset represents a sequence of the same amount of consecutive data values in the primary data set that has a second slope variance value being lower than the first slope variance value. Hence, any raw data segments showing a relatively high slope variability will be represented by comparatively many data points in the secondary data set, whereas raw data segments showing a relatively low slope variability will be represented by comparatively few data points in the secondary data set.

According to yet another embodiment of this aspect of the invention, the at least one processing unit is further configured to estimate an amount of forthcoming milking-related raw data that will be obtained in at least one future milking process based on at least one earlier obtained primary data set. Moreover, the at least one processing unit is configured to assign the data compressing parameter based on the estimated amount of forthcoming milking-related raw data and at least one storage-limiting parameter. Consequently, a particular storage space may be economized to ensure that a required amount of data can be stored therein.

The at least one storage-limiting parameter may pertain to a capacity of a local data store and/or a remote data store. Here, the local data store is presumed to be co-located with the milking plant where the milking-related raw data is produced. The remote data store is configured to store the secondary data set of two or more geographically separated milking plants, and is thus located at a distance from at least one of these milking plants.

According to still another embodiment of this aspect of the invention, the at least one processing unit is configured to assign the data compressing parameter based on a bandwidth limitation of a transmission channel arranged to transmit the secondary data set to a central server. Thereby, the data compression may for example be adjusted dynamically in response to a current capacity of the transmission channel, and it can be guaranteed that no data needs to be discarded due to bottleneck issues.

According to another embodiment of this aspect of the invention, the milking plant contains a local data store, and the at least one processing unit is further configured to temporarily store the primary data set in the local data store before mapping the original number of data values onto the available number of data positions in the secondary data set. This enables optimizing the overall mapping process because the mapping process can be effected after that all data in the primary data set is available to the at least one processing unit.

For efficiency reasons, the secondary data set may be stored in the local data store where the primary data set is temporarily stored.

According to a further embodiment of this aspect of the invention, the at least one processing unit is configured to adapt the mapping of the primary data set onto the secondary data set to the slope variability in the primary data set by means of: curve fitting the data positions in the secondary data set to slope variations in the primary data set, which slope variations exceed a first threshold value; curve fitting the data positions in the secondary data set based on a second derivative of the primary data set, which second derivative exceeds a second threshold value; and/or fitting the data positions in the secondary data set to the primary data set through a linear optimization procedure. Thus, the at least one data compression algorithm may be adapted inter alia to the characteristics of the milking-related raw data and/or the capacity of the at least one processing unit.

According to yet other embodiments of this aspect of the invention, the milking-related raw data represents: a milk flow rate registered via a sensor device including a milk flow meter; a milk conductivity registered via a sensor device comprising a conductivity sensor; a relative amount of blood in milk registered via a sensor device including a color sensitive light sensor; a relative amount of fat in milk registered via a sensor device comprising an electro-magnetic field sensor configured to produce absorption-spectrum data; a relative amount of protein in milk registered via a sensor device including an electro-magnetic field sensor configured to produce absorption-spectrum data; a relative amount of lactose in milk registered via a sensor device including an electro-magnetic field sensor configured to produce absorption-spectrum data; a vacuum pressure level inside a pulsation chamber of a milking cup registered via a sensor device (205) comprising a vacuum sensor configured to produce vacuum pressure data and/or a vacuum pressure level inside a milk transport line that is connected to a milking cup registered via a sensor device (205) comprising a vacuum sensor configured to produce vacuum pressure data. As a result a wide variety of parameters may be analyzed and evaluated.

According to another embodiment of this aspect of the invention, the primary and the secondary data sets represent series of measurement values arranged in a chronological order. In other words, the raw data may describe one or more parameters as functions over time.

According to another aspect of the invention, the object is achieved by a computer-implemented method for processing milking-related raw data produced by at least one sensor device comprised in milking point of a milking plant, which milking point is arranged to extract milk from an animal. The method is performed in at least one processor and involves: obtaining a primary data set containing an original number of data values representing the milking-related raw data; obtaining a data compressing parameter forming a basis for a secondary data set comprising a reduced number of data positions, which reduced number is lower than the original number; mapping the original number of data values onto the reduced number of data positions to generate the secondary data set by applying at least one data compression algorithm; and outputting the secondary data set via an output interface to enable storage of the secondary data set in at least one data store. The advantages of this method, as well as the preferred embodiments thereof, are apparent from the discussion above with reference to the proposed milking plant.

According to a further aspect of the invention, the object is achieved by a computer program loadable into a non-volatile data carrier communicatively connected to a processing unit. The computer program includes software for executing the above method when the program is run on the processing unit.

According to another aspect of the invention, the object is achieved by a non-volatile data carrier containing the above computer program.

Further advantages, beneficial features and applications of the present invention will be apparent from the following description and the dependent claims.

### BRIEF DESCRIPTION OF THE DRAWINGS

The invention is now to be explained more closely by means of preferred embodiments, which are disclosed as examples, and with reference to the attached drawings.

FIG. 1a shows a first example of a primary data set according to one embodiment of the invention;

FIG. 1b shows a secondary data set onto which the primary data set of FIG. 1a has been mapped by applying a data compression algorithm according to one embodiment of the invention;

FIG. 2 shows a milking plant including a number of processing units and a communication system according to one embodiment of the invention;

FIG. 3a shows a second example of a primary data set according to one embodiment of the invention;

FIG. 3b shows a secondary data set onto which the primary data set of FIG. 3a has been mapped by applying a data compression algorithm according to one embodiment of the invention; and

FIG. 4 illustrates, by means of a flow diagram, the general method according to the invention.

### DETAILED DESCRIPTION

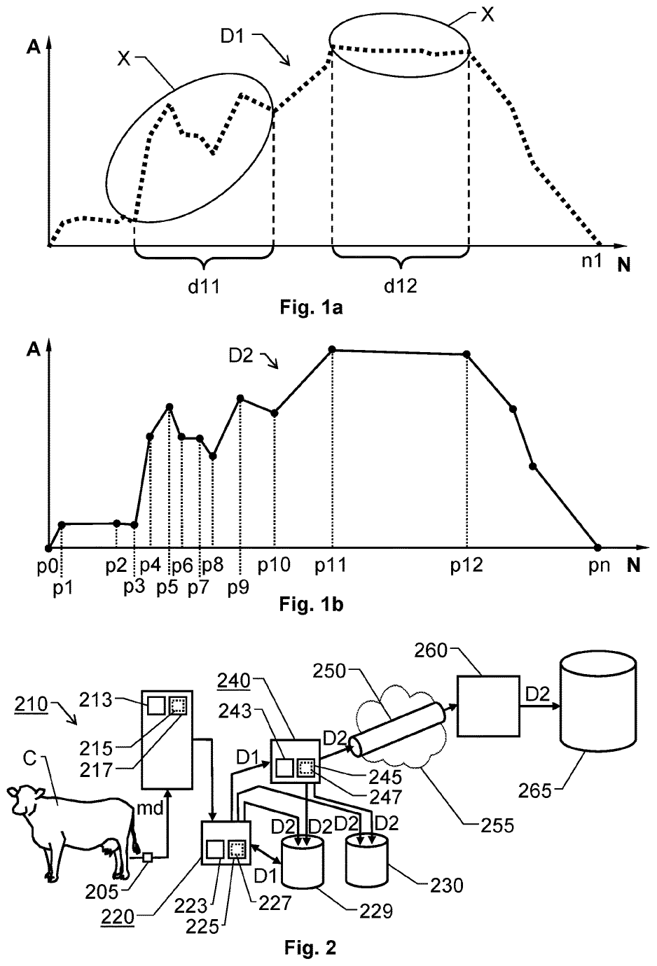

In FIG. 1a, we see a first example of a primary data set D1 according to one embodiment of the invention, and FIG. 2 shows a milking plant with local processing units represented by a first processor 213 configured to handle milking-related raw data md produced at a milking point 210 that is arranged to extract milk from an animal C, a second processor 223 in a farm computer 220 and a third processor 243 in a gateway computer 240 of the farm where the milking plant is located. FIG. 2 also shows a central server 260 communicatively connected to the gateway computer 240 via a transmission channel 250 through at least one network 255, e.g. represented by the Internet.

Typically, the milking plant would contain a plurality of milking points 210. For clarity reasons, however, this is not illustrated in FIG. 2.

The milking point 210 includes at least one sensor device 205 configured to produce the milking-related raw data md during the extraction of the milk from the animal C. Preferably, the milking-related raw data md cover a complete milking session during which milk is extracted from the animal C. This namely facilitates drawing appropriate conclusions about the milking process as such, the milk extracted during this process and/or the health status of the animal. Alternatively, the milking point 210 may for example include at least one sensor device 205 configured to register milking-related raw data md representing a pulsation cycle reflecting how the vacuum pressure level varies inside a pulsation chamber of a milking cup.

According to different embodiments of the invention, the sensor device 205 may be implemented by a wide variety of sensors. For example, the sensor device 205 may contain a milk flow meter configured to register a milk flow rate representing the milking-related raw data md. Alternatively, or additionally, the sensor device 205 may contain a conductivity sensor configured to register a milk conductivity of the milk extracted from the animal C to represent the milking-related raw data md. Alternatively, or additionally, the sensor device 205 may contain a color sensitive light sensor, e.g. an RBG sensor, configured to register a relative amount of blood in the milk extracted from the animal C to represent the milking-related raw data md. Alternatively, or additionally, the sensor device 205 may contain an electro-magnetic field sensor configured to produce absorption-spectrum data representing a relative amount of fat, a relative amount of protein and/or a relative amount of lactose in the milk extracted from the animal C as the milking-related raw data md.

Any one of the processing units 213, 223 and/or 243 may be configured to obtain the primary data set D1, which comprises an original number n1 of data values A representing the milking-related raw data md. Either the primary data set D1 is processed in a first processing unit 213 in which the primary data set D1 is obtained, or the first processing unit 213 forwards the primary data set D1 to another processing unit, for instance in the farm computer 220 or in the gateway computer 240 for processing. Primarily, the choice of processing unit depends on where a most critical bottleneck is located. Namely, the primary data set D1 should preferably be processed upstream of such a bottleneck to reduce a transmission load and/or storage load on the equipment constituting the bottleneck.

The processing unit 213, 223 or 243 chosen to be responsible for processing the primary data set D1 is configured to obtain a data compressing parameter, which forms a basis for a secondary data set D2. As will be described below, the data compressing parameter, in turn, may be assigned based on various grounds.

FIG. 1b shows an example of the secondary data set D2 onto which the primary data set D1 of FIG. 1a has been mapped by applying a data compression algorithm according to one embodiment of the invention.

The data compression algorithm, in turn, is implemented in the processing unit 213, 223 or 243, for example by running a computer program stored on a data carrier 215, 225 or 245 that is communicatively connected to the processing unit 213, 223 or 243 respectively.

The secondary data set D2 contains a reduced number of data positions p0, p1, p2, p3, p4, p5, p6, p7, p8, p9, p10, p11, p12, . . . , pn, which reduced number pn+1 is lower than the original number n1. For example, in FIG. 1a, the original number n1 of data values A may be 400, representing 400 seconds of milk-related raw data md in the form of a milk flow rate sampled at 1 Hz, and the reduced number pn+1 of data values A may be 20, 40 or 80, corresponding to an average sampling rate of 0.05 Hz, 0.1 Hz or 0.2 Hz respectively. However, in contrast to the data values A in the primary data set D1, the reduced number of data positions pn+1 in the secondary data set D2 do not represent a uniform sampling, i.e. where the sampling points are equidistant.

Instead, the intermediate distances between the sampling points represented by the reduced number of data positions pn+1 in the secondary data set D2 depend on an information density of a signal underlying the milk-related raw data md. Thus, if, locally, the data values A in the primary data set D1 show a relatively high degree of slope variability, this portion of the primary data set D1 will correspond to relatively many of the data positions in the secondary data set D2. Analogously, if, locally, the data values A in the primary data set D1 show a relatively low degree of slope variability, this portion of the primary data set D1 will correspond to relatively few of the data positions in the secondary data set D2. In other words, the secondary data set D2 represents a non-uniform sampling of the primary data set D1, which non-uniform sampling is such that intermediate distances between the sampling points in the set of sampling points represented by the reduced number of data positions in the secondary data set D2 is inversely correlated with the information density of a signal underlying the milk-related raw data md.

The processing unit 213, 223 or 243 is configured to attain the above non-uniform sampling of the milk-related raw data md as expressed in the secondary data set D2 by mapping the original number n1 of data values A in the primary data set D1 onto the reduced number of data positions pn+1 by applying at least one data compression algorithm. According to one embodiment of the invention, the processing unit 213, 223 or 243 is configured to apply the at least one data compression algorithm by adapting the mapping of the original number of data values A onto the reduced number of data positions to the slope variability in the primary data set D1 such that a first subset d11 of the primary data set D1, which first subset d11 represents a sequence of an amount X of consecutive data values A and has a first slope variance value is mapped onto a larger number of the available number of data positions p0, p1, p2, p3, p4, p5, p6, p7, p8, p9, p10; p11, p12, . . . , pn in the secondary data set D2 than a second subset d12 of the primary data D1 set if the second subset d12 represents a sequence of the amount X of consecutive data values A in the primary data set D1 that has a second slope variance value being lower than the first slope variance value.

According to another embodiment of the invention, the processing unit 213, 223 or 243 is configured to map of the primary data set D1 onto the secondary data set D2 to the slope variability in the primary data set D1 by means of curve fitting the data positions p0, p1, p2, p3, p4, p5, p6, p7, p8, p9, p10; p11, p12, . . . , pn in the secondary data set D2 to slope variations in the primary data set D1. Here, a condition for mapping a particular data value A from the primary data set D1 onto a data position in the secondary data set D2 is that the primary data set must have a slope variation above a first threshold value around the particular data value A. The first threshold value, in turn, is preferably assigned based on the data compression parameter, such that if the data compression parameter specifies a relatively high degree of compression, the first threshold value is comparatively high, and vice versa.

According to yet another embodiment of the invention, the processing unit 213, 223 or 243 is configured to map of the primary data set D1 onto the secondary data set D2 to the slope variability in the primary data set D1 by means of curve fitting the data positions p0, p1, p2, p3, p4, p5, p6, p7, p8, p9, p10; p11, p12, . . . , pn in the secondary data set D2 based on a second derivative of the primary data set D1. Analogous to the above, a condition for mapping a particular data value A from the primary data set D1 onto a data position in the secondary data set D2 is that the second derivative exceed the second threshold value around the particular data value A. The second threshold value, in turn, is preferably assigned based on the data compression parameter, such that if the data compression parameter specifies a relatively high degree of compression, the second threshold value is comparatively high, and vice versa.

According to yet another embodiment of the invention, the processing unit 213, 223 or 243 is configured to map of the primary data set D1 onto the secondary data set D2 to the slope variability in the primary data set D1 by means of curve fitting the data positions p0, p1, p2, p3, p4, p5, p6, p7, p8, p9, p10; p11, p12, . . . , pn in the secondary data set D2 through a linear optimization procedure, or so-called linear programming. Thus, here, the processing unit 213, 223 or 243 applies a set of linear equality and linear inequality constraints to obtain a best fitting of the secondary data set D2 to the data values A in the primary data set D1.

Finally, the processing unit 213, 223 or 243 is configured to output the secondary data set D2 via an output interface to enable the secondary data set D2 to be stored in at least one data store, for example in a local data store in the form of a first database 229 in the farm computer 220, a second database 230 in the gateway computer 240 and/or in a remote data store in the form of a third database 265 associated with the central server 260.

Thus, each of the local data stores 229 and 230 is co-located with the milking plant where the milking-related raw data md is produced, and the remote data store 265 is typically situated at a location geographically separated from this milking plant. Nevertheless, it is not excluded that the remote data store 265 is co-located with a particular milking plant.

In such a case, the remote data store 265 may be configured to store the secondary data set D2 of at least one other milking plant being geographically separated therefrom.

According to one embodiment of the invention, the milking-related raw data md contains respective information identifying the milking point 210 containing the at least one sensor device 205 from which the milking-related raw data md originates. Said identification information constitutes a minimal load in terms of bandwidth/storage space and is therefore preferably mapped into the secondary data set D2 whenever available via the primary data set D1.

To enable appropriate planning of how the primary data set D1 is to be mapped onto the secondary data set D2, according to one embodiment of the invention, based on at least one earlier obtained primary data set D1, the processing unit 213, 223 or 243 is configured to estimate an amount of forthcoming milking-related raw data md that will be obtained in at least one future milking process. The processing unit 213, 223 or 243 is further configured to assign the data compressing parameter based on the estimated amount of forthcoming milking-related raw data md and at least one storage-limiting parameter. Thus, for example, the processing unit 213, 223 or 243 may apply the at least one data compression algorithm such that a number of primary data sets D1 are mapped into the same number of secondary data sets D2, where each secondary data sets D2 contains a suitable reduced number of data positions given the at least one storage-limiting parameter, e.g. reflecting an available amount of storage space.

Here, the at least one storage-limiting parameter may pertain to a local data store, such as one or both of the databases 229 and 230 as well as a remote data store, such as the database 265.

Moreover, it is advantageous if the processing unit 213, 223 or 243 is configured to assign the data compressing parameter based on a bandwidth limitation of the transmission channel 250, which is arranged to transmit the secondary data set D2 to the central server 260. Namely, the transmission channel 250 as such may constitute the bottleneck for process of storing a representation of the milking-related raw data md.

According to one embodiment of the invention, the milking plant contains a local data store 229, for example communicatively connected to the farm computer 220. Here, the processing unit, e.g. 223 in the farm computer 220, is configured to temporarily store the primary data set D1 in the local data store 229 before mapping the original number of data values A onto the available number of data positions p0, p1, p2, p3, p4, p5, p6, p7, p8, p9, p10; p11, p12, . . . , pn in the secondary data set D2. Thereby, the processing unit 223 has access to the entire primary data set D1 before initiating mapping of the primary data set D1 onto the secondary data set D2. This is beneficial because it enables to fully optimize the mapping onto the available number of data positions p0, p1, p2, p3, p4, p5, p6, p7, p8, p9, p10; p11, p12, . . . , pn given the constraints expressed by the data compression parameter.

Further, after having derived the secondary data set D2, the processing unit 223 (or 213 or 243 respectively) may be configured to store the secondary data set D2 in the local data store 229 where the primary data set D1 was temporarily stored. However, depending on the implementation, the processing unit 223 or 213 or 243 may equally well be configured to store the secondary data set D2 in an alternative data store, such as for example the local data store 230 and/or the remote data store 265.

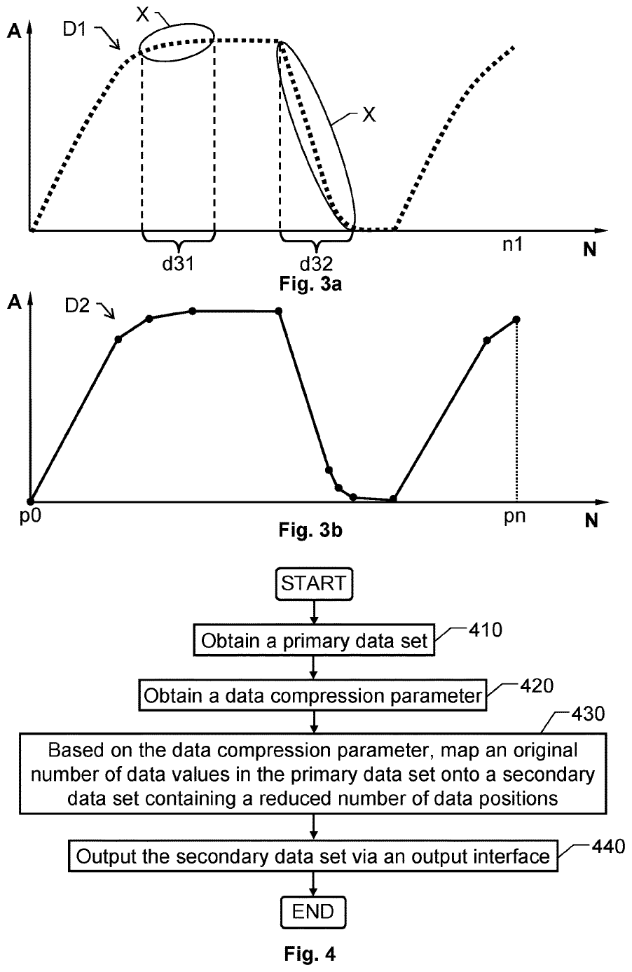

FIGS. 3a and 3b show a second example of the primary data set D1 and the secondary data set D2 respectively according to one embodiment of the invention. Here, the primary data set D1 is presumed to describe a pulsation cycle. The pulsation cycle may thus reflect how the vacuum pressure level varies inside a pulsation chamber of a milking cup. The pulsation chamber is typically represented by the space between the liner and the shell of a teacup. In general, the vacuum pressure level is registered by a vacuum sensor. It is to be noted that the vacuum sensor may be arranged to measure indirectly the vacuum pressure level prevailing in the pulsation chamber. The vacuum sensor does not need to be arranged in the pulsation chamber as such. The vacuum sensors is typically arrange in a line that supplies either under pressure or atmospheric pressure to the pulsation chamber.

Preferably, the n1 data values A of the milking-related raw data md in the primary data set D1 cover at least one complete pulsation cycle.

Compared to the milk flow curve exemplified in FIG. 1a, the pulsation cycle of FIG. 3a is a relatively quick process, which may be completed in approximately one second. Therefore, the sampling frequency applied to the milking-related raw data md to obtain the primary data set D1 representing the pulsation cycle may be in the range of 100 Hz to 1000 Hz. However, the milk-related raw data md is processed by the processing unit 213, 223 or 243 according the same principles as described above.

For example, according to one embodiment of the invention, the processing unit 213, 223 or 243 may be configured to apply the at least one data compression algorithm by adapting the mapping of the original number of data values A onto the reduced number of data positions to the slope variability in the primary data set D1 such that a first subset d32 of the primary data set D1, which first subset d32 represents a sequence of an amount X of consecutive data values A and has a first slope variance value is mapped onto a larger number of the available number of data positions p0, . . . , pn in the secondary data set D2 than a second subset d31 of the primary data D1 set if the second subset d31 represents a sequence of the amount X of consecutive data values A in the primary data set D1 that has a second slope variance value being lower than the first slope variance value.

Analogous to FIGS. 1a and 1b, the abscissas in FIGS. 3a and 3b designate time, i.e. the primary and the secondary data sets D1 and D2 respectively represent series of measurement values arranged in a chronological order. According to embodiments of the invention, however, any alternative series of data values my be represented, for example a total amount of milk extracted from the animal C.

In a further embodiment the milking-related raw data (md) represents a vacuum pressure level inside a milk transport line that is connected to the milking cup registered via a sensor device (205) comprising a vacuum sensor configured to produce vacuum pressure data. In this further embodiment, the sampling frequency applied to the milking-related raw data md to obtain the primary data set D1 representing vacuum level prevailing inside the milk line connected to the milking cup may be in the range of 10 Hz to 100 Hz. Also in this embodiment the vacuum sensor may be arranged to measure indirectly the vacuum level inside the milk transport line that is connected to the milking cup.

In order to sum up, and with reference to the flow diagram in FIG. 4, we will now describe the computer-implemented method according to the invention which is performed in the processor 213, 223 or 243 of the milking point 210, farm computer 220 or the gateway computer 240 respectively.

In a step 410, a primary data set D1 obtained, which primary data set D1 contains an original number of data values A representing milking-related raw data md.

In a step 420 that may be executed prior to, in parallel with or subsequent to step 410, a data compressing parameter is obtained, which data compressing parameter forms a basis for a secondary data set D2, which contains a reduced number of data positions relative to the original number of data values in the primary data set D1. Basically, the data compressing parameter specifies an amount of compression to be made from the primary data set D1 to the secondary data set D2.

In a step 430 following steps 410 and 420, the original number of data values A are mapped onto the reduced number of data positions to generate the secondary data set D2 based on the data compressing parameter and by applying at least one data compression algorithm.

Subsequently, in a step 440, the secondary data set D2 is output via an output interface to enable the secondary data set D2 to be stored in at least one data store, for example in one or more of the above-mentioned databases 229, 230 and/or 265.

Thereafter, the procedure ends.

The process steps described with reference to FIG. 4 may be controlled by means of a programmed processor. Moreover, although the embodiments of the invention described above with reference to the drawings comprise processor and processes performed in at least one processor, the invention thus also extends to computer programs, particularly computer programs on or in a carrier, adapted for putting the invention into practice. The program may be in the form of source code, object code, a code intermediate source and object code such as in partially compiled form, or in any other form suitable for use in the implementation of the process according to the invention. The program may either be a part of an operating system, or be a separate application. The carrier may be any entity or device capable of carrying the program. For example, the carrier may comprise a storage medium, such as a Flash memory, a ROM (Read Only Memory), for example a DVD (Digital Video/Versatile Disk), a CD (Compact Disc) or a semiconductor ROM, an EPROM (Erasable Programmable Read-Only Memory), an EEPROM (Electrically Erasable Programmable Read-Only Memory), or a magnetic recording medium, for example a floppy disc or hard disc. Further, the carrier may be a transmissible carrier such as an electrical or optical signal which may be conveyed via electrical or optical cable or by radio or by other means. When the program is embodied in a signal, which may be conveyed, directly by a cable or other device or means, the carrier may be constituted by such cable or device or means. Alternatively, the carrier may be an integrated circuit in which the program is embedded, the integrated circuit being adapted for performing, or for use in the performance of, the relevant processes.

Variations to the disclosed embodiments can be understood and effected by those skilled in the art in practicing the claimed invention, from a study of the drawings, the disclosure, and the appended claims.

The term “comprises/comprising” when used in this specification is taken to specify the presence of stated features, integers, steps or components.

The term does not preclude the presence or addition of one or more additional elements, features, integers, steps or components or groups thereof. The indefinite article “a” or “an” does not exclude a plurality. In the claims, the word “or” is not to be interpreted as an exclusive or (sometimes referred to as “XOR”). On the contrary, expressions such as “A or B” covers all the cases “A and not B”, “B and not A” and “A and B”, unless otherwise indicated. The mere fact that certain measures are recited in mutually different dependent claims does not indicate that a combination of these measures cannot be used to advantage. Any reference signs in the claims should not be construed as limiting the scope.

It is also to be noted that features from the various embodiments described herein may freely be combined, unless it is explicitly stated that such a combination would be unsuitable.

The invention is not restricted to the described embodiments in the figures, but may be varied freely within the scope of the claims.

1. A milking plant comprising:
at least one milking point (210) arranged to extract milk from an animal (C), the at least one milking point comprising:
at least one sensor device (205) configured to produce milking-related raw data (md) during extraction of milk from the animal (C), and
at least one processor (213, 223, 243) configured to:
obtain a primary data set (D1) comprising an original number of data values (A) representing the milking-related raw data,
obtain a data compressing parameter forming a basis for a secondary data set (D2) comprising a reduced number of data positions (p0, . . . , pn), the reduced number of data positions being lower than the original number of data positions,
map the original number of data values (A) onto the reduced number of data positions (p0, . . . , pn) to generate the secondary data set (D2) by applying at least one data compression algorithm, and
output the secondary data set (D2) via an output interface to enable storage of the secondary data set (D2) in at least one data store (229, 230, 265).

2. The milking plant according to claim 1, wherein the secondary data set (D2) represents a non-uniform sampling of the primary data set (D1), the non-uniform sampling being such that intermediate distances between sampling points in a set of sampling points represented by the reduced number of data positions (p0, . . . , pn) in the secondary data set (D2) is inversely correlated with an information density of a signal underlying the milk-related raw data (md).

3. The milking plant according to claim 1, wherein the milking-related raw data (md) comprises respective information identifying each of the at least one milking point (210) comprising the at least one sensor device (205).

4. The milking plant according to claim 1, wherein the at least one processor (213, 223, 243) is further configured to apply the at least one data compression algorithm by adapting the mapping of the original number of data values (A) onto the reduced number of data positions to a slope variability in the primary data set (D1) such that a first subset (d11, d32) of the primary data set (D1), which the first subset (d11, d32) representing a sequence of a number (X) of consecutive data values (A) and having a first slope variance value, is mapped onto a larger number of available said data positions (p3, p4, p5, p6, p7, p8, p9, p10; p11, p12, . . . , pn) in the secondary data set (D2) than a second subset (d12, d31) of the primary data (D1) set if the second subset (d12, d31) represents a sequence of the amount number (X) of consecutive data values (A) in the primary data set (D1) that has a second slope variance value being that is lower than the first slope variance value.

5. The milking plant according to claim 1, wherein the at least one processor (213, 223, 243) is further configured to:
estimate an amount of forthcoming milking-related raw data (md) that will be obtained in at least one future milking process based on at least one earlier obtained said primary data set (D1), and
assign the data compressing parameter based on the estimated amount of forthcoming milking-related raw data (md) and at least one storage-limiting parameter.

6. The milking plant according to claim 5, wherein the at least one storage-limiting parameter pertains to at least one of a local data store (229, 230) and a remote data store (265), the local data store (229, 230) being co-located with the milking plant where the milking-related raw data (md) is produced, and the remote data store (265) being configured to store the secondary data set (D2) of two or more geographically separated said milking plants.

7. The milking plant according to claim 1, wherein the at least one processor (213, 223, 243) is configured to:
assign the data compressing parameter based on a bandwidth limitation of a transmission channel (250) arranged to transmit the secondary data set (D2) to a central server (260).

8. The milking plant according to claim 1, further comprising a local data store (229), the at least one processor (213, 223, 243) being further configured to:
temporarily store the primary data set (D1) in the local data store (229) before mapping the original number of data values (A) onto the available number of data positions (p0, . . . , pn) in the secondary data set (D2).

9. The milking plant according to claim 8, wherein the at least one processor (213, 223, 243) is further configured to:
store the secondary data set (D2) in the local data store (229) where the primary data set (D1) is temporarily stored.

10. The milking plant according to claim 4, wherein the at least one processor (213, 223, 243) is further configured to adapt the mapping of the primary data set (D1) onto the secondary data set (D2) to the slope variability in the primary data set (D1) using at least one of:
curve fitting the data positions (p0, . . . , pn) in the secondary data set (D2) to slope variations in the primary data set (D1), the slope variations exceeding a first threshold value,
curve fitting the data positions (p0, . . . , pn) in the secondary data set (D2) based on a second derivate derivative of the primary data set (D1), the second derivate exceeding a second threshold value, and
fitting the data positions (p0, . . . , pn) in the secondary data set (D2) to the primary data set (D1) through a linear optimization procedure.

11. The milking plant according to claim 1, wherein the milking-related raw data (md) represents at least one of:
a milk flow rate, wherein the at least one sensor device comprises a milk flow meter configured to produce the milk flow rate,
a milk conductivity, wherein the at least one sensor device comprises a conductivity sensor configured to produce the milk conductivity,
a relative amount of blood in the milk, wherein the at least one sensor device comprises color sensitive light sensor configured to produce the relative amount of blood in the milk,
a relative amount of fat in milk, wherein the at least one sensor device comprises an electro-magnetic field sensor configured to produce absorption-spectrum data identifying the relative amount of the fat in the milk,
a relative amount of protein in milk, wherein the at least one sensor device comprises an electro-magnetic field sensor configured to produce absorption-spectrum data identifying the relative amount of the protein in the milk,
a relative amount of lactose in milk, wherein the at least one sensor device comprises an electro-magnetic field sensor configured to produce absorption-spectrum data identifying the relative amount of the lactose in the milk,
a vacuum pressure level inside a pulsation chamber of a milking cup, wherein the at least one sensor device comprises a vacuum sensor configured to produce vacuum pressure data identifying the vacuum pressure level inside the pulsation chamber of the milking cup, and
a vacuum pressure level inside a milk transport line connected to a milking cup, wherein the at least one sensor device comprises a vacuum sensor configured to product vacuum pressure data identifying the vacuum pressure level inside the milk transport line connected to the milking cup.

12. The milking plant according to claim 1, wherein the primary and the secondary data sets (D1; D2) represent a series of measurement values arranged in a chronological order.

13. The milking plant according to claim 1, wherein the milking-related raw data (md) cover a complete milking session during which the milk was extracted from the animal (C).

14. A computer-implemented method for processing milking-related raw data (md) produced by at least one sensor device (205) comprised in milking point (210) of a milking plant, the milking point being arranged to extract milk from an animal (C), the method being performed in at least one processor (213, 223, 243), the method comprising:
obtaining a primary data set (D1) containing an original number of data values (A) representing the milking-related raw data (md),
obtaining a data compressing parameter forming a basis for a secondary data set (D2) comprising a reduced number of data positions (p0, . . . , pn), the reduced number of data positions being lower than the original number of data positions,
mapping the original number of data values (A) onto the reduced number of data positions (p0, . . . , pn) to generate the secondary data set (D2) by applying at least one data compression algorithm, and
outputting the secondary data set (D2) via an output interface to enable storage of the secondary data set (D2) in at least one data store (229, 230, 265).

15. The method according to claim 14, wherein the secondary data set (D2) represents a non-uniform sampling of the primary data set (D1), the non-uniform sampling being such that intermediate distances between the sampling points in a set of sampling points represented by the reduced number of data positions (p0, . . . , pn) in the secondary data set (D2) is inversely correlated with an information density of a signal underlying the milk-related raw data (md).

16. The method according to claim 14, wherein the milking-related raw data (md) comprises respective information identifying each of the at least one milking point (210) comprising the at least one sensor device (205).

17. The method according to claim 14, further comprising:
applying the at least one data compression by adapting the mapping of the original number of data values (A) onto the reduced number of data positions to a slope variability in the primary data set (D1) such that a first subset (d11, d32) of the primary data set (D1), the first subset (d11, d32) representing a sequence of a number (X) of consecutive data values (A) and having a first slope variance value, is mapped onto a larger number of the available number of data positions (p3, p4, p5, p6, p7, p8, p9, p10; p11, p12, . . . , pn) in the secondary data set (D2) than a second subset (d12, d31) of the primary data (D1) set if the second subset (d12, d31) represents a sequence of the number (X) of consecutive data values (A) in the primary data set (D1) that has a second slope variance value that is lower than the first slope variance value.

18. The method according to claim 14, further comprising:
estimating an amount of forthcoming milking-related raw data (md) that will be obtained in at least one future milking process based on at least one earlier obtained said primary data set (D1), and
assigning the data compressing parameter based on the estimated amount of forthcoming milking-related raw data (md) and at least one storage-limiting parameter.

19. The method according to claim 18, wherein the at least one storage-limiting parameter pertains to at least one of a local data store (229, 230) and a remote data store (265), the local data store (229, 230) being co-located with the milking plant where the milking-related raw data (md) is produced, the remote data store (265) being configured to store the secondary data set (D2) of two or more geographically separated milking plants.

20. The method according to claim 14, further comprising:
assigning the data compressing parameter based on a bandwidth limitation of a transmission channel (250) arranged to transmit the secondary data set (D2) to a central server (260).

21. The method according to claim 17, wherein the adapting of the mapping of the primary data set (D1) onto the secondary data set (D2) to the slope variability in the primary data set (D1) comprises at least one of:
curve fitting the data positions (p0, . . . , pn) in the secondary data set (D2) to slope variations in the primary data set (D1), the slope variations exceeding a first threshold value,
curve fitting the data positions (p0, . . . , pn) in the secondary data set (D2) based on a second derivative of the primary data set (D1), the second derivative exceeding a second threshold value, and
fitting the data positions (p0, . . . , pn) in the secondary data set (D2) to the primary data set (D1) through a linear optimization procedure.

22. The method according to claim 14, wherein the primary and the secondary data sets (D1; D2) represent a series of measurement values arranged in a chronological order.

23. The method according to claim 14, wherein the milking-related raw data (md) cover a complete milking session during which the milk was extracted from the animal (C).

24. A non-volatile computer-readable medium on which is stored a computer program (217, 227, 247) communicatively connected to a processor (213, 223, 243), the computer program (217, 227, 247) comprising software for executing the method according claim 14 when the computer program (217, 227, 247) is run on the processor (213, 223, 243).

25. (canceled)

26. The milking plant of claim 1, wherein the at least one processor is further configured to:
estimate an amount of forthcoming said milking-related raw data (md) that will be obtained in at least one future milking process based on at least one earlier obtained said primary data set (D1), and
assign the data compressing parameter based on the estimated amount of forthcoming milking-related raw data (md).

27. The method of claim 14, further comprising:
estimating an amount of forthcoming said milking-related raw data (md) that will be obtained in at least one future milking process based on at least one earlier obtained said primary data set (D1), and
assigning the data compressing parameter based on the estimated amount of forthcoming milking-related raw data (md).

28. A milking plant comprising:
at least one milking point arranged to extract milk from an animal, the at least one milking point comprising:
at least one sensor device configured to produce milking-related raw data during extraction of the milk from the animal; and
at least one processor configured to:
obtain a primary data set comprising an original number of data values representing the milking-related raw data,
obtain a data compressing parameter indicative of estimated forthcoming data volume or transmission bandwidth limitation, the data compressing parameter being used to determine threshold criteria for selecting data positions to be retained in a secondary data set comprising a reduced number of data positions, the reduced number being lower than the original number,
map the original number of data values onto the reduced number of data positions to generate the secondary data set by applying at least one data compression algorithm that adapts the mapping based on the data compressing parameter, and
output the secondary data set to at least one data store.

29. A computer-implemented method for processing milking-related raw data produced by at least one sensor device comprised in milking point of a milking plant, the milking point being arranged to extract milk from an animal, the method being performed in at least one processor, the method comprising:
obtaining a primary data set containing an original number of data values representing the milking-related raw data;
obtaining a data compressing parameter indicative of estimated forthcoming data volume or transmission bandwidth limitation, the data compressing parameter forming a basis for controlling one or more threshold values that govern selection of data points to be included in a secondary data set comprising a reduced number of data positions, the reduced number of data positions being lower than the original number of data positions;
mapping the original number of data values onto the reduced number of data positions to generate the secondary data set by applying at least one data compression algorithm that adaptively selects data points for retention based on the data compressing parameter; and
outputting the secondary data set to at least one data store.
